(19) United States
(12) Patent Application Publication
(10) Pub. No.: US 2025/0364987 A1
(43) Pub. Date: Nov. 27, 2025

(54) SEMICONDUCTOR INTEGRATED CIRCUIT

(71) Applicant: WILL SEMICONDUCTOR (SHANGHAI) CO. LTD., SHANGHAI (CN)

(72) Inventor: MASAMI AIURA, MIYAGI (JP)

(21) Appl. No.: 18/886,019

(22) Filed: Sep. 16, 2024

(30) Foreign Application Priority Data
May 24, 2024 (JP) 2024-085165

(51) Int. Cl. H03K 17/51

(52) U.S. Cl. CPC H03K 17/51

(57) ABSTRACT

[Problem to be solved] The disclosure is to omit a complicated compensation circuit and the like.

[Solution] The disclosure has an internal power supply line VHI that outputs an internal power supply voltage generated based on an external power supply 10, and an internal block 14 is connected to the internal power supply line VHI. The disclosure includes: an internal ground line SUB, which is the ground of the internal power supply line VHI; an external ground terminal 12b, to which the ground of the external power supply 10 is connected; a rectifying element M4, which is disposed between the internal ground line SUB and the external ground terminal 12b and makes a current flow toward the external ground terminal 12b; and a reference circuit 16, which generates a reference voltage. The ground of the reference circuit 16 is connected to the external ground terminal 12b via a first individual transistor M7.

### BACKGROUND OF THE INVENTION

### 1. Field of the Invention

The disclosure relates to a semiconductor integrated circuit, which has an internal power supply line that outputs an internal power supply voltage generated based on an external power supply, and in which an internal circuit is connected to the internal power supply line.

### 2. Description of the Related Art

A semiconductor integrated circuit such as large scale integration (LSI) normally receives power supply supplied from the outside. Therefore, an external power supply line is connected to a power supply terminal arranged in the semiconductor integrated circuit. In this case, a rectifying circuit may be arranged internally when the external power supply is an alternating-current power supply, or to address reverse connection of the external power supply line. The rectifying circuit is often configured by a bridge obtained using rectifying elements of transistors and diodes.

### PRIOR ART DOCUMENTS

### Patent Documents

[Patent document 1] Japanese Patent Laid-Open No. 2016-220351

### SUMMARY OF THE INVENTION

### Problems to be Solved

Here, when the rectifying circuit is arranged, a current flows from the ground of an internal power supply line to the ground of the external power supply line via the rectifying element.

In this case, due to a voltage drop of the rectifying element, the ground level of the internal power supply line of the semiconductor integrated circuit is higher than the ground potential of the external power supply line. Thus, in a circuit operating by using the ground level of the external power supply line as a standard, an offset caused by the voltage drop of the rectifying element must be considered, which complicates the circuit for compensation.

### Means to Solve Problems

A semiconductor integrated circuit related to the disclosure is
a semiconductor integrated circuit, which has an internal power supply line that outputs an internal power supply voltage generated based on an external power supply, and in which an internal block is connected to the internal power supply line,
the semiconductor integrated circuit includes:
an internal ground line, which is the ground of the internal power supply line;
an external ground terminal, to which the ground of the external power supply is connected;
a rectifying element, which is disposed between the internal ground line and the external ground terminal and makes a current flow toward the external ground terminal; and
a reference circuit, which generates a reference voltage; wherein
the ground of the reference circuit is connected to the external ground terminal via a first individual transistor.

### Effects

According to the semiconductor integrated circuit related to the disclosure, a complicated compensation circuit and the like can be omitted by arranging a dedicated rectifier having a relatively simple configuration.

### BRIEF DESCRIPTION OF THE DRAWINGS

FIG. 1 is a circuit diagram showing the configuration of a semiconductor integrated circuit according to an embodiment.

FIG. 2 is a circuit diagram showing the configuration of a variant.

### PREFERRED EMBODIMENT OF THE PRESENT INVENTION

Hereinafter, embodiments of the disclosure are described below with reference to the drawings. Note that, the following embodiments do not limit the scope of the disclosure, and configurations obtained by selectively combining multiple examples are also included in the disclosure.

### “Overall Configuration”

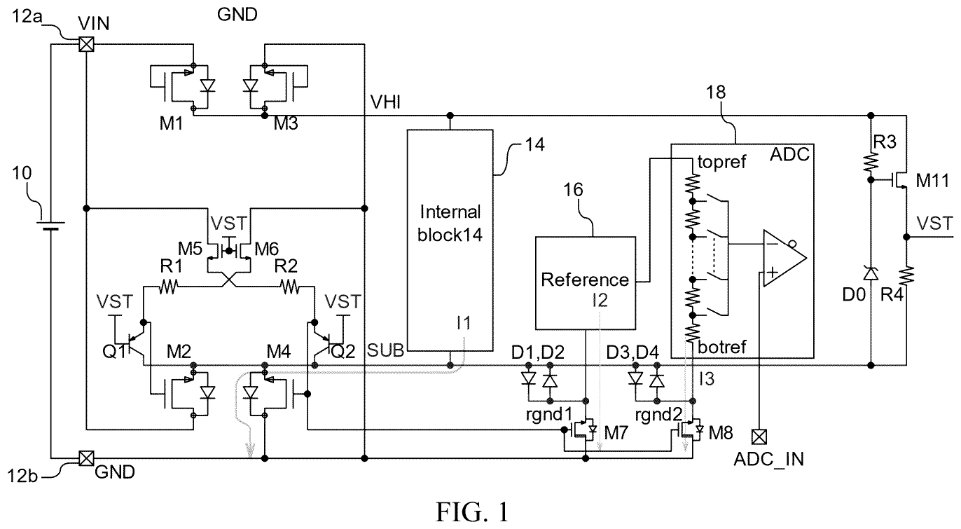

FIG. 1 is a circuit diagram showing the configuration of a semiconductor integrated circuit according to an embodiment. A direct-current voltage from an external power supply 10 is supplied to an input terminal 12a and an input terminal 12b. In the illustrated example, it is assumed that an external upper voltage VIN is supplied to the input terminal 12a and an external lower voltage GND is input to the input terminal 12b. In this case, the input terminal 12a corresponds to an external power supply terminal, and the input terminal 12b corresponds to an external ground terminal.

Note that, there is no problem even if the external power supply 10 is reversely connected, the external lower voltage GND is supplied to the input terminal 12a, and the external upper voltage VIN is input to the input terminal 12b. In addition, it is also possible to supply an alternating-current voltage.

Four transistors M1, M2, M3 and M4 are connected to form a transistor bridge serving as a rectifying circuit. The source of the transistor M1 and the drain of the transistor M2 are connected. The source of the transistor M3 and the drain of the transistor M4 are connected. The drain of the transistor M1 and the drain of the transistor M3 are connected. In addition, the source of the transistor M2 and the source of the transistor M4 are connected.

In this example, the transistors M1, M2, M3 and M4 are n-channel metal-oxide-semiconductor field effect transistors (MOSFETs), but it is also possible to use p-channel transistors, bipolar transistors, or the like.

The input terminal 12a is connected to a connection point between the source of the transistor M1 and the drain of the transistor M2, and the input terminal 12b is connected to a connection point between the source of the transistor M3 and the drain of the transistor M4.

In addition, the drain of the transistor M1 and the drain of the transistor M3 are connected to an internal upper line VHI. The source of the transistor M2 and the source of the transistor M4 are connected to an internal lower line SUB. The upper line VHI is the internal power supply line, the lower line SUB is the internal ground line, and the voltage therebetween is the internal power supply voltage. The input terminal 12a is connected to the gate of the transistor M4 via a transistor M5 and a resistor R2. The gate of the transistor M4 is connected to the lower line SUB via a transistor Q2. The transistor Q2 is a pnp transistor, the emitter of the transistor Q2 is connected to the gate of the transistor M4, the collector of the transistor Q2 is connected to the lower line SUB, and a clamp voltage VST is supplied to the base of the transistor Q2. The input terminal 12b is connected to the gate of the transistor M2 via a transistor M6 and a resistor R1. The gate of the transistor M2 is connected to the lower line SUB via a transistor Q1. The transistor Q1 is a pnp transistor, the emitter of the transistor Q1 is connected to the gate of the transistor M2, the collector of the transistor Q1 is connected to the lower line SUB, and the clamp voltage VST is supplied to the base of the transistor Q1. The transistors M5 and M6 are n-channel transistors.

One end of a resistor R3 is connected to the upper line VHI, the other end of the resistor R3 is connected to the cathode of a zener diode DO, and the anode of the zener diode DO is connected to the lower line SUB. A connection point between the resistor R3 and the zener diode DO is connected to the gate of an n-channel transistor M11. The drain of the transistor M11 is connected to the upper line VHI and the source of the transistor M11 is connected to the lower line SUB via a resistor R4. Additionally, the clamp voltage VST is taken out from a connection point between the source of the transistor M11 and the resistor R4.

In this kind of circuit, a voltage is applied from the upper line VHI to the zener diode DO via the resistor R3. If the cathode voltage of the zener diode DO is equal to or greater than the breakdown voltage of the zener diode DO, the cathode voltage of the zener diode DO becomes a breakdown voltage Vbr. Accordingly, the gate voltage of the transistor M11 becomes Vbr, and the source voltage thereof becomes a voltage which is lower than the gate voltage by Vgs, that is, VST=Vbr−Vgs. In this way, the clamp voltage VST can be set according to the breakdown voltage of the zener diode DO.

The gates of the transistors M5 and M6 are commonly connected, and the clamp voltage VST is supplied thereto. Moreover, the clamp voltage VST is also supplied to the bases of the transistors Q1 and Q2. Therefore, the source voltages of the transistors M5 and M6 are clamped to VST−Vgs, and the bases of the transistors Q1 and Q2 are clamped to VST+Vbe. Accordingly, the gate voltages of the transistors M2 and M4 are clamped to a predetermined voltage, and the transistors M2 and M4 can be protected. In addition, a rapid change in the current is moderated by the resistors R1 and R2.

The transistors M1 and M3 are short-circuited between the gate and the source to function as diodes. Accordingly, a voltage corresponding to the external upper voltage VIN input to either the input terminal 12a or the input terminal 12b is set for the upper line VHI. Note that, in the transistor M1 or M3, a forward voltage drop caused by the diode occurs, and VHI=VIN−Vf. Note that, the above Vf is a voltage drop of a parasitic diode of the transistor M3 or the transistor M1.

When the external upper voltage VIN is input to the input terminal 12a and the external lower voltage GND is input to the input terminal 12b, the transistor M4 is turned on and the transistor M2 is turned off, thereby supplying the external upper voltage VIN to the upper line VHI and supplying the external lower voltage GND to the lower line SUB.

In addition, when the external upper voltage VIN is input to the input terminal 12b and the external lower voltage GND is input to the input terminal 12a, the transistor M2 is turned on and the transistor M4 is turned off, thereby supplying the external upper voltage VIN to the upper line VHI and supplying the external lower voltage GND to the lower line SUB.

Note that, the transistors Q1 and Q2 are normally off because the clamp voltage VST is supplied to the bases. On the other hand, when the external upper voltage VIN is supplied to one of the input terminal 12a and the input terminal 12b, the gate voltage of the transistor M2 or the transistor M4 may rise greatly. In this example, the transistors M2 and M4 can be protected by, as described above, clamping the voltage by the transistors M5 and M6 and suppressing the rise by the resistor R1 or R2, and additionally, turning on the transistor Q1 or Q2.

Additionally, an internal block 14 is connected to the upper line VHI and the lower line SUB. The internal block 14 is a circuit that receives power supply supplied from the upper line VHI and the lower line SUB and operates, and various circuits are adopted hereinto according to the purpose of the semiconductor integrated circuit.

Moreover, a reference circuit 16 that generates a reference voltage is arranged inside the semiconductor integrated circuit. The reference circuit 16 is connected to the upper line VHI and the lower line SUB and generates the reference voltage in the normal case.

In the embodiment, the ground side of the reference circuit 16 is not directly connected to the lower line SUB, but is connected to the input terminal 12b via the n-channel first individual transistor M7. The gate of the first individual transistor M7 is connected to the gate of the transistor M4, and the first individual transistor M7 is turned on/off similarly to the transistor M4, and bypasses the transistor M4 to connect the ground of the reference circuit 16 to the input terminal 12b.

In addition, an ADC (analog-to-digital converter) 18 that AD-converts an analog signal into digital data is arranged inside the semiconductor integrated circuit. In this example, an analog signal input from a terminal ADC_IN is converted into digital data. The obtained digital data is preferably processed by a digital data processing unit inside the semiconductor integrated circuit.

The ADC 18 compares the reference voltage supplied from the reference circuit 16 with the input analog signal, and outputs the comparison result. For example, the reference voltage is resistance-divided to obtain a plurality of divided voltages, and each divided voltage is compared with the input analog signal to obtain digital data to be output based on the results that the input analog signal is higher than which one or ones of the divided voltages and also is lower than which one or ones of the divided voltages.

In this example, the ADC 18 obtains the divided voltages by a plurality of resistors disposed between an upper voltage topref which is the power supply voltage and a lower voltage botref which is the ground. Additionally, the lower voltage botref is connected to the input terminal 12b via an n-channel second individual transistor M8. The second individual transistor M8 is turned on/off similarly to the transistor M4, and bypasses the transistor M4 to connect the ground of the ADC 18 to the input terminal 12b.

In this way, in the embodiment, the reference circuit 16 and the ADC 18 are connected to the input terminal 12b by the individual transistors M7 and M8, respectively. Thus, a current I1 from the internal block 14 flows to the input terminal 12b via the transistor M4, a current I2 from the reference circuit 16 flows to the input terminal 12b via the transistor M7, and a current I3 from the ADC 18 flows to the input terminal 12b via the transistor M8. Thus, the currents flowing to the individual transistors M7 and M8 are just the currents flowing to the reference circuit 16 and the ADC 18, respectively. That is, the currents flowing to the reference circuit 16 and the ADC 18 can be prevented from flowing to the transistor M4 together with a current flowing to the internal block 14 and being affected by a voltage drop in the transistor M4.

Generally, a current used for reference is much smaller than, for example, 1/500 to 1/10,000 of, a current consumed by the entire semiconductor integrated circuit, and therefore dedicated rectifiers such as the individual transistors M7 and M8 can be mounted in a small area.

In addition, the ground of the reference circuit 16 is connected to the internal lower line SUB by diodes D1 and D2 that constitute a bidirectional circuit. The ground of the ADC 18 is connected to the internal lower line SUB by diodes D3 and D4 that constitute a bidirectional circuit.

When the external power supply 10 is reversely connected to the input terminals 12a and 12b, the transistor M4 is turned off and the transistor M2 is turned on. Because the transistor M4 is turned off, the individual transistors M7 and M8 are also turned off. Thus, the grounds of the reference circuit 16 and the ADC 18 will not be connected to anywhere, but because of the existence of the diodes D1 and D2 and the diodes D3 and D4 that make a bidirectional current flow, the grounds of the reference circuit 16 and the ADC 18 are connected to the internal lower line SUB via the diodes D1 and D2 and the diodes D3 and D4. Accordingly, it is possible to solve problems such as unnecessary voltage application to the internal elements when the external power supply 10 is reversely connected.

### “Variant”

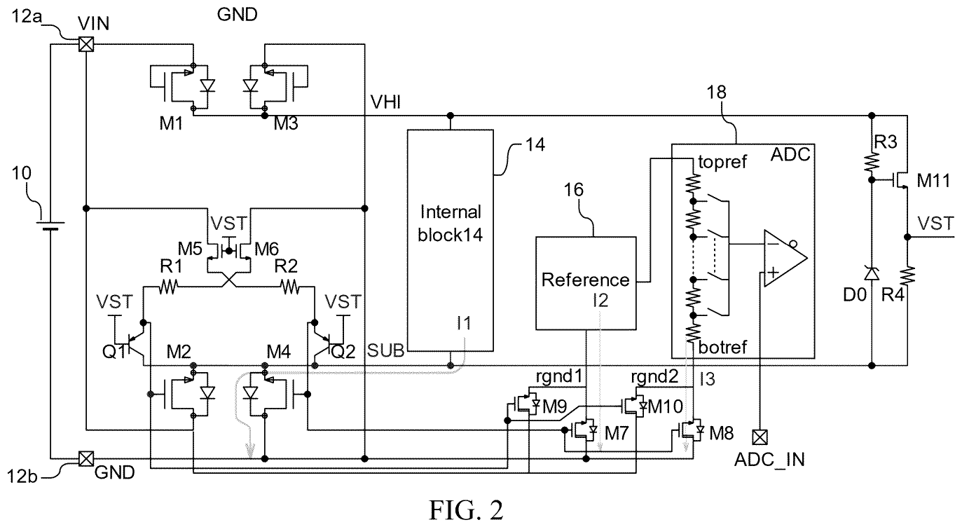

FIG. 2 is a circuit diagram showing the configuration of a variant. In this variant, an n-channel transistor M9 is used instead of the diodes D1 and D2, and an n-channel transistor M10 is used instead of the diodes D3 and D4.

The ground of a reference circuit 16 is connected to an input terminal 12a by the transistor M9, and the ground of an ADC 18 is connected to the input terminal 12a by the transistor M10. Furthermore, the gates of the transistors M9 and M10 are connected to the gate of a transistor M2.

Thus, when an external power supply 10 is reversely connected to the input terminal 12a and an input terminal 12b, the transistor M2 is turned on, and the transistors M9 and M10 are turned on. Thus, both the reference circuit 16 and the ADC 18 can operate as they are.

### Effects of Embodiments

In the circuits shown in FIGS. 1 and 2, a bridge-type rectifier is built in to address the reverse connection of the external power supply. In this case, due to a voltage drop of the rectifying element (such as M4 in FIG. 1), the ground (such as SUB in FIG. 1) level inside LSI is higher than the potential of the ground (such as GND in FIG. 1) connected externally. Thus, when considering the use of a voltage with respect to the external ground level, an offset caused by the voltage drop of the rectifying element must be considered, which complicates the circuit for compensation.

Offset correction can also be performed by taking out the internal ground potential as the external terminal and referring to this potential as the ground level. However, a separate circuit for compensation is also required in this case.

In the embodiment, a dedicated rectifier (such as M7 and M8 in FIG. 1) is prepared for a reference block and the like. A voltage drop of this dedicated rectifier is only the product of its equivalent resistance and energizing current, and is not affected by other consumption currents. As described above, the current used for reference is much smaller than ( 1/500 to 1/10,000 of) the current consumed by the entire LSI, and therefore the dedicated rectifier can be mounted in a small area.

In this way, according to the semiconductor integrated circuit according to the embodiment, a complicated compensation circuit and the like can be omitted by arranging a dedicated rectifier having a relatively simple configuration.

### DESCRIPTION OF THE REFERENCE NUMERALS

10: external power supply
12a: input terminal
12b: input terminal
14: internal block
16: reference circuit

What is claimed is:

1. A semiconductor integrated circuit, which has an internal power supply line that outputs an internal power supply voltage generated based on an external power supply, and in which an internal block is connected to the internal power supply line,
the semiconductor integrated circuit comprising:
an internal ground line, which is the ground of the internal power supply line;
an external ground terminal, to which the ground of the external power supply is connected;
a rectifying element, which is disposed between the internal ground line and the external ground terminal and makes a current flow toward the external ground terminal; and
a reference circuit, which generates a reference voltage; wherein
the ground of the reference circuit is connected to the external ground terminal via a first individual transistor.

2. The semiconductor integrated circuit according to claim 1,
further
having an ADC that performs an AD conversion with reference to the reference voltage, wherein
the ground of the ADC is connected to the external ground terminal via a second individual transistor.

3. The semiconductor integrated circuit according to claim 1, wherein
a connection point between the ground line and the first individual transistor and the ground of the internal power supply line are connected by a bidirectional circuit, and
when a power supply voltage is applied to the external ground terminal and the first individual transistor is off, the ground of the internal power supply line is connected to an external power supply terminal.

4. The semiconductor integrated circuit according to claim 1, wherein
the external power supply terminal and the internal power supply line are connected via a rectifying circuit, and
the rectifying element is included in the rectifying circuit.
